(19) United States
(12) Patent Application Publication
(10) Pub. No.: US 2026/0254239 A1
(43) Pub. Date: Aug. 27, 2026

(54) METHOD, APPARATUS AND DEVICE FOR DETERMING VOLTAGE SUPPORT STRENGTH OF RENEWABLE ENERGY POWER SYSTEM IN REAL TIME, STORAGE MEDIUM AND COMPUTER PROGRAM PRODUCT

(71) Applicant: CHINA ELECTRIC POWER RESEARCH INSTITUTE, Beijing (CN)

(72) Inventors: Huadong SUN, Beijing (CN); Lin YU, Beijing (CN); Shiyun XU, Beijing (CN); Long PENG, Beijing (CN); Hongfu WANG, Beijing (CN); Bing ZHAO, Beijing (CN); Gongwei XI, Beijing (CN)

(21) Appl. No.: 18/726,478

(22) PCT Filed: Dec. 20, 2023
(86) PCT No.: PCT/CN2023/140332

§ 371 Date: Jul. 3, 2024

(30) Foreign Application Priority Data
Jun. 20, 2023 (CN) 202310728273.7

(51) Int. Cl. H02J 3/0012; G01R 19/10; G01R 31/52; H02J 3/18; H02J 103/30

(52) U.S. Cl. CPC H02J 3/0012; G01R 19/10; G01R 31/52; H02J 3/18; H02J 2103/30

(57) ABSTRACT

Provided are a method, apparatus and device for determining voltage support strength of a renewable energy power system in real time, a storage medium and a computer program product. The method includes following operations. A bus real-time operating voltage and a collection line current of a monitoring point of the renewable energy power system are collected; a system's Thevenin equivalent potential of the monitoring point is calculated according to the bus real-time operating voltage and the collection line current; a short circuit ratio of the monitoring point and a critical short circuit ratio of the monitoring point are calculated according to a nominal voltage of the monitoring point, the system's Thevenin equivalent potential and the bus real-time operating voltage; a safety margin of the short circuit ratio of the monitoring point is calculated according to the short circuit ratio of the monitoring point and the critical short circuit ratio of the monitoring point; and a strength division result of the voltage support strength of the renewable energy power system is determined according to the safety margin of the short circuit ratio of the monitoring point and a set voltage support strength division criterion. The method greatly reduces electrical parameters involved in the calculation of the short circuit ratio, improves algorithm efficiency and provides technical support for strength division of the voltage support strength.

### CROSS-REFERENCE TO RELATED APPLICATION

This application is based on and claims priority to Chinese patent application No. 202310728273.7 filed on Jun. 20, 2023 and entitled “METHOD AND APPARATUS FOR DETERMINING VOLTAGE SUPPORT STRENGTH OF RENEWABLE ENERGY POWER SYSTEM IN REAL TIME”, the contents of which are hereby incorporated by reference in its entirety.

### TECHNICAL FIELD

The present disclosure relates to but is not limited to the field of power system security analysis, in particular to a method, apparatus and device for determining voltage support strength of a renewable energy power system in real time, a storage medium and a computer program product.

### BACKGROUND

With the integration of wind power plants, photovoltaic plants and other renewable energy plants into the traditional power network, a renewable energy power system has been gradually formed. Due to the regional and seasonal imbalance of wind power resources and photoelectric resources, the consumption, energy storage and transmission of wind power resources and photoelectric resources in the renewable energy power system have increasingly become obstacles restricting the renewable energy power system in development and exerting potential. If the system cannot provide enough voltage support, large-scale safe and reliable power transmission of renewable energy cannot be realized. It is required to monitor voltage support strength at key points of the renewable energy system in real time, and pay attention to voltage support strength provided by the system, so as to ensure the transmission scale of the renewable energy within a safe range.

The output of the renewable energy has the characteristics of randomness and fluctuation, which leads to the complex and changeable operation mode of the power system, and further increases the difficulty in real-time monitoring of voltage support strength of the system. At present, the voltage support strength of the system is analyzed by calculating a short circuit ratio of a terminal bus of a renewable energy unit or a short circuit ratio of a bus of a renewable energy plant. The short circuit ratio is calculated by offline data. The short circuit ratio cannot be measured in real time based on local real-time measurement information. The real-time measurement of the short circuit ratio has great hysteresis in time. After the output level of the renewable energy changes or a system is disturbed, operators cannot obtain the present short circuit ratio of the system in a timely manner, and cannot analyze the voltage support strength of the system, thus being unable to provide reference for optimization and adjustment for control strategy in a timely manner.

### SUMMARY

The present disclosure proposes a method, apparatus and device for determining voltage support strength of a renewable energy power system in real time, a storage medium and a computer program product.

In a first aspect, an embodiment of the present disclosure provides a method for determining voltage support strength of a renewable energy power system in real time. The method includes following operations.

A bus real-time operating voltage and a collection line current of a monitoring point of the renewable energy power system are collected. The renewable energy power system includes at least one renewable energy plant, and each renewable energy plant includes at least one renewable energy unit. The monitoring point is a bus of a renewable energy plant or a terminal bus of a renewable energy unit.

A system's Thevenin equivalent potential of the monitoring point is calculated according to the bus real-time operating voltage and the collection line current.

A short circuit ratio of the monitoring point and a critical short circuit ratio of the monitoring point are calculated according to a nominal voltage of the monitoring point, the system's Thevenin equivalent potential and the bus real-time operating voltage.

A safety margin of the short circuit ratio of the monitoring point is calculated according to the short circuit ratio of the monitoring point and the critical short circuit ratio of the monitoring point.

A strength division result of the voltage support strength of the renewable energy power system is determined according to the safety margin of the short circuit ratio of the monitoring point and a set voltage support strength division criterion.

In a second aspect, an embodiment of the present disclosure provides an apparatus for determining voltage support strength of a renewable energy power system in real time. The apparatus includes a data collection module, a first calculation module, a second calculation module, a third calculation module and a result output module.

The data collection module is configured to collect a bus real-time operating voltage and a collection line current of a monitoring point of the renewable energy power system. The renewable energy power system includes at least one renewable energy plant, and each renewable energy plant includes at least one renewable energy unit. The monitoring point is a bus of a renewable energy plant or a terminal bus of a renewable energy unit.

The first calculation module is configured to calculate a system's Thevenin equivalent potential of the monitoring point according to the bus real-time operating voltage and the collection line current.

The second calculation module is configured to calculate a short circuit ratio of the monitoring point and a critical short circuit ratio of the monitoring point according to a nominal voltage of the monitoring point, the system's Thevenin equivalent potential and the bus real-time operating voltage.

The third calculation module is configured to calculate a safety margin of the short circuit ratio of the monitoring point according to the short circuit ratio of the monitoring point and the critical short circuit ratio of the monitoring point.

The result output module is configured to determine a strength division result of the voltage support strength of the renewable energy power system according to the safety margin of the short circuit ratio of the monitoring point and a set voltage support strength division criterion.

In a third aspect, an embodiment of the present disclosure provides a device for determining voltage support strength of a renewable energy power system in real time. The device includes a memory and a processor. The memory is used for storing computer executable instructions. The processor is coupled to the memory and is configured to execute the computer executable instructions to perform the method as described in the first aspect.

In a fourth aspect, an embodiment of the present disclosure provides a computer-readable storage medium, having stored thereon a computer program that, when executed by at least one processor, performs the method as described in the first aspect.

In a fifth aspect, an embodiment of the present disclosure provides a computer program product including computer instructions that, when running on a computer device, cause the computer device to perform the method as described in the first aspect.

According to the method, apparatus and device for determining the voltage support strength of the renewable energy power system in real time, the storage medium and the computer program product, a bus real-time operating voltage and a collection line current of a monitoring point of the renewable energy power system are collected; a system's Thevenin equivalent potential of the monitoring point is calculated according to the bus real-time operating voltage and the collection line current; a short circuit ratio of the monitoring point and a critical short circuit ratio of the monitoring point are calculated according to a nominal voltage of the monitoring point, the system's Thevenin equivalent potential and the bus real-time operating voltage; a safety margin of the short circuit ratio of the monitoring point is calculated according to the short circuit ratio of the monitoring point and the critical short circuit ratio of the monitoring point; and a strength division result of the voltage support strength of the renewable energy power system is determined according to the safety margin of the short circuit ratio of the monitoring point and a set voltage support strength division criterion. According to the method, voltage support strength of the system is evaluated through the electrical quantities collected by a power system measuring apparatus in real time, and the related electrical quantities only include a bus operation voltage of the monitoring point, the collection line current, a rated voltage of the renewable energy plant and a rated voltage of the renewable energy unit, thus greatly reducing the number of electrical parameters involved in the calculation of the short circuit ratio, improving algorithm efficiency and realizing real-time monitoring of the voltage support strength of the system.

### BRIEF DESCRIPTION OF THE DRAWINGS

Exemplary embodiments of the present disclosure may be more fully understood by reference to the following drawings.

FIG. 1 illustrates a flowchart of a method for determining voltage support strength of a renewable energy power system in real time according to a preferred embodiment of the present disclosure.

FIG. 2 illustrates a structural diagram of an apparatus for determining voltage support strength of a renewable energy power system in real time according to a preferred embodiment of the present disclosure.

### DETAILED DESCRIPTION

Exemplary embodiments of the present disclosure are now described with reference to the accompanying drawings. However, the present disclosure may be embodied in many different forms and is not limited to the embodiments described herein, which are provided to disclose the present disclosure in detail and completely, and to fully convey the scope of the present disclosure to those skilled in the art. Terms referred to in the exemplary embodiments in the drawings are not limiting to the present disclosure. In the drawings, the same reference numerals are used for the same units/elements.

Unless otherwise stated, terms (including technical terms) used herein have a common understanding meaning to those skilled in the art to which they pertain. In addition, it is understandable that terms defined in commonly used dictionaries should be understood to have meanings consistent with the context of their related fields, and should not be understood as having idealistic meanings or overly formal meanings.

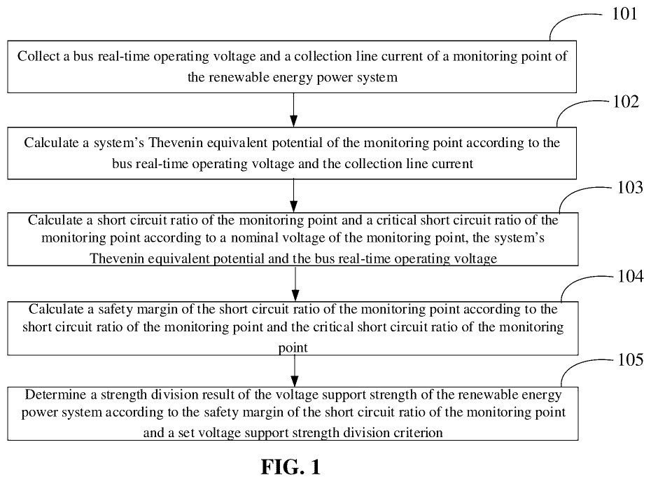

FIG. 1 illustrates a flowchart of a method for determining voltage support strength of a renewable energy power system in real time according to a preferred embodiment of the present disclosure. As illustrated in FIG. 1, the method for determining the voltage support strength of the renewable energy power system in real time according to the present preferred embodiment starts from an operation 101.

In the operation 101, a bus real-time operating voltage and a collection line current of a monitoring point of the renewable energy power system are collected. The renewable energy power system includes at least one renewable energy plant, and each renewable energy plant includes at least one renewable energy unit. The monitoring point is a bus of a renewable energy plant or a terminal bus of a renewable energy unit.

There may be one or more monitoring points of the renewable energy power system in the present disclosure. When there are multiple monitoring points, the multiple monitoring points can be numbered, and the calculation is performed on the multiple numbered monitoring points in sequence according to the technical solutions for obtaining the short circuit ratio, the critical short circuit ratio and the safety margin of the short circuit ratio according to the preferred embodiment. When a safety margin of a short circuit ratio of any one of the multiple monitoring points meets the set voltage support strength division criterion, the strength division result of the voltage support strength of the renewable energy power system can be determined.

In an operation 102, a system's Thevenin equivalent potential of the monitoring point is calculated according to the bus real-time operating voltage and the collection line current.

Preferably, a system's Thevenin equivalent potential of the monitoring point is calculated according to the bus real-time operating voltage and the collection line current, and a calculation formula of the system's Thevenin equivalent potential is shown as the formula (1):

$${\dot{E}}_{t} = \frac{{\dot{U}}_{t} {\dot{I}}_{t - 1} - {\dot{U}}_{t - 1} {\dot{I}}_{t}}{{\dot{I}}_{t - 1} - {\dot{I}}_{t}} \qquad ( 1 )$$

In the formula, \dot{U}ₜ is a bus operating voltage of the monitoring point at a moment t, \dot{U}ₜ₋₁ is a bus operating voltage of the monitoring point at a moment t−1, İₜ is a collection line current of the monitoring point at the moment t, İₜ₋₁ is a collection line current of the monitoring point at the moment t−1, and Ėₜ is a system's Thevenin equivalent potential of the monitoring point at the moment t.

In the preferred embodiment, for the bus operating voltage \dot{U}ₜ₋₁ of the monitoring point collected at the moment t−1 and the collection line current İₜ₋₁ of the monitoring point collected at the moment t−1, a result of the formula (2) can be obtained according to a calculation formula of a system bus voltage:

$${\dot{U}}_{t - 1} = {\dot{E}}_{t - 1} + {Z}_{t - 1} {\dot{I}}_{t - 1} \qquad ( 2 )$$

In the formula, Ėₜ₋₁ is a system's Thevenin equivalent potential of the monitoring point at the moment t−1, and Zₜ₋₁ is a system's Thevenin equivalent impedance of the monitoring point at the moment t−1.

Similarly, for the bus operating voltage \dot{U}ₜ of the monitoring point collected at the moment t and the collection line current İₜ of the monitoring point collected at the moment t, a result of the formula (3) can be obtained according to the calculation formula of the system bus voltage:

$${\dot{U}}_{t} = {\dot{E}}_{t} + {Z}_{t} {\dot{I}}_{t} \qquad ( 3 )$$

In the formula, Ėₜ is a system's Thevenin equivalent potential of the monitoring point at the moment t, and Zₜ is a system's Thevenin equivalent impedance of the monitoring point at the moment t.

When renewable energy output of the renewable energy power system fluctuates, the system's Thevenin equivalent potential and the system's Thevenin equivalent impedance can be approximately regarded as unchanged, and the formula (4) and the formula (5) can be obtained:

$${\dot{E}}_{t} = {\dot{E}}_{t - 1} \qquad ( 4 )$$

$${Z}_{t} = {Z}_{t - 1} \qquad ( 5 )$$

Therefore, according to the simultaneous solution of the above four formulas, the calculation formula (6) for solving the system's Thevenin equivalent potential of the monitoring point at the moment t described in the embodiment can be obtained:

$${\dot{E}}_{t} = \frac{{\dot{U}}_{t} {\dot{I}}_{t - 1} - {\dot{U}}_{t - 1} {\dot{I}}_{t}}{{\dot{I}}_{t - 1} - {\dot{I}}_{t}} \qquad ( 6 )$$

In an operation 103, a short circuit ratio of the monitoring point and a critical short circuit ratio of the monitoring point are calculated according to a nominal voltage of the monitoring point, the system's Thevenin equivalent potential and the bus real-time operating voltage.

Preferably, a short circuit ratio of the monitoring point and a critical short circuit ratio of the monitoring point are calculated according to a nominal voltage of the monitoring point, the system's Thevenin equivalent potential and the bus real-time operating voltage, and a calculation formula of the short circuit ratio of the monitoring point and a calculation formula of the critical short circuit ratio of the monitoring point are shown as the formula (7) and the formula (8), respectively:

$$SCR - {U}_{t} = \frac{{U}_{N} \cdot {E}_{t}}{{U}_{t} \cdot \vert {\dot{U}}_{t} - {\dot{E}}_{t} \vert} \qquad ( 7 )$$

$$CSCR - {U}_{t} = \frac{{U}_{N} {E}_{t}}{{U}_{t}^{2}} \qquad ( 8 )$$

In the formulas SCR-Uₜ is a short circuit ratio of the monitoring point at a moment t, and CSCR-Uₜ is a critical short circuit ratio of the monitoring point at the moment t. Ėₜ is a system's Thevenin equivalent potential of the monitoring point at the moment t. Eₜ is a modulus value of the system's Thevenin equivalent potential of the monitoring point at the moment t. \dot{U}ₜ is a bus operating voltage of the monitoring point at the moment t. Uₜ is a modulus value of the bus operating voltage of the monitoring point at the moment t. U_{N} is the nominal voltage of the monitoring point. When the monitoring point is a bus of a renewable energy plant, a value of U_{N} is a rated voltage of a voltage class corresponding to the renewable energy plant, and when the monitoring point is a terminal bus of a renewable energy unit in a renewable energy plant, the value of U_{N} is a rated voltage of the renewable energy unit.

The real-time calculation method of the critical short circuit ratio provided by the embodiment of the present disclosure provides a stable criterion for judging the safety margin of the voltage support strength of the system.

In the preferred embodiment, the monitoring point can not only be a bus of a renewable energy plant, but also a terminal bus of a renewable energy unit in a renewable energy plant. Therefore, a nominal voltage of the monitoring point is assigned with different values according to the above two different situations. When the monitoring point is a bus of renewable energy plant, a value of the nominal voltage is a rated voltage of a voltage class corresponding to the renewable energy plant, such as 35 kV, 110 kV, 220 kV, 330 kV, etc. When the monitoring point is a terminal bus of a renewable energy unit, a value of the nominal voltage is a rated device voltage, such as 0.4 kV, 0.69 kV, etc.

In an operation 104, a safety margin of the short circuit ratio of the monitoring point is calculated according to the short circuit ratio of the monitoring point and the critical short circuit ratio of the monitoring point.

Preferably, a safety margin of the short circuit ratio of the monitoring point is calculated according to the short circuit ratio of the monitoring point and the critical short circuit ratio of the monitoring point, and a calculation formula of the safety margin of the short circuit ratio of the monitoring point is shown as the formula (9):

$$M {g}_{t} = \frac{SCR - {U}_{t} - CSCR - {U}_{t}}{SCR - {U}_{t}} \times 100 \qquad ( 9 )$$

In the formula, Mgₜ is the safety margin of the short circuit ratio of the monitoring point, which is expressed as a percentage and is dimensionless. SCR-Uₜ is a short circuit ratio of the monitoring point at a moment t. CSCR-Uₜ is a critical short circuit ratio of the monitoring point at the moment t.

In an operation 105, a strength division result of the voltage support strength of the renewable energy power system is determined according to the safety margin of the short circuit ratio of the monitoring point and a set voltage support strength division criterion.

Preferably, a strength division result of the voltage support strength of the renewable energy power system is determined according to the safety margin of the short circuit ratio of the monitoring point and a set voltage support strength division criterion, and the voltage support strength division criterion includes followings.

In response to Mgₜ<K₁, it is determined that the renewable energy power system is a system with weak voltage support strength, where K₁ is a safety margin of the short circuit ratio of the monitoring point determined through calculation when an operating voltage becomes lower than a voltage threshold K₄ via low voltage ride through for an operating condition where reactive power compensation of the renewable energy power system is K₃, 0<K₁, K₃, K₄<1.

In response to K₁≤Mgₜ<K₂, it is determined that the renewable energy power system is a system with medium voltage support strength, where K₂ is a safety margin of the short circuit ratio of the monitoring point determined through calculation when renewable energy active power output reaches K₅ of transmission capacity of the renewable energy power system for an operating condition where reactive power compensation of the renewable energy power system is K₃, 0<K₂, K₅<1.

In response to Mgₜ≥K₂, it is determined that the renewable energy power system is a system with strong voltage support strength.

The voltage support strength division criterion provided by the embodiment of the present disclosure provides technical support for strength division of the voltage support strength.

In the preferred embodiment, when K₃=15% and K₄=0.9p. u, K₁=22% can be obtained according to the calculation formula for calculating the short circuit ratio, the critical short circuit ratio and the safety margin of the short circuit ratio. In the same way, when K₃=15% and K₅=80%, K₂=32% can be obtained according to the calculation formulas for calculating the short circuit ratio, the critical short circuit ratio and safety margin of the short circuit ratio. Therefore, the criterion for judging strength of the voltage support strength of the renewable energy power system based on the safety margins of the short circuit ratio K₁=22% and K₂=32% are as follows.

In response to Mgₜ<22%, it is determined that the renewable energy power system is a system with weak voltage support strength.

In response to 22%≤Mgₜ<32%, it is determined that the renewable energy power system is a system with medium voltage support strength.

In response to Mgₜ≥32%, it is determined that the renewable energy power system is a system with strong voltage support strength.

According to the method for determining the voltage support strength of the renewable energy power system according to the preferred embodiment, the short circuit ratio and the critical short circuit ratio can be obtained based on the bus real-time operating voltage and the collection line current of the monitoring point of the renewable energy power system collected in real time, and the technical solution of determining the voltage support strength of the system by determining the safety margin of the short circuit ratio of the system according to the obtained short circuit ratio and the critical short circuit ratio is provided. The method involves few electrical parameters in real time calculation of the voltage support strength of the renewable energy power system, has fast speed of calculation, and has high real-time performance and practicability.

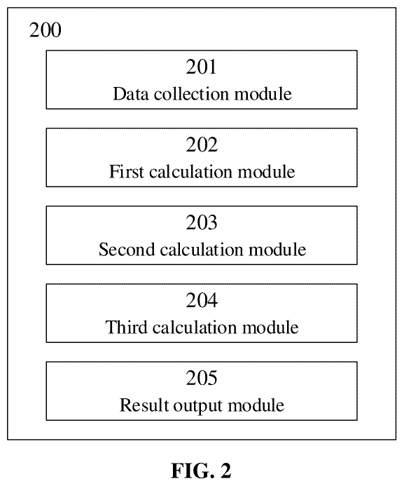

FIG. 2 illustrates a structural diagram of an apparatus for determining voltage support strength of a renewable energy power system in real time according to a preferred embodiment of the present disclosure. As illustrated in FIG. 2, the apparatus 200 for determining the voltage support strength of the renewable energy power system in real time according to the present preferred embodiment includes a data collection module 201, a first calculation module 202, a second calculation module 203, a third calculation module 204 and a result output module 205.

The data collection module 201 is configured to collect a bus real-time operating voltage and a collection line current of a monitoring point of the renewable energy power system. The renewable energy power system includes at least one renewable energy plant, and each renewable energy plant includes at least one renewable energy unit. The monitoring point is a bus of a renewable energy plant or a terminal bus of a renewable energy unit.

The first calculation module 202 is configured to calculate a system's Thevenin equivalent potential of the monitoring point according to the bus real-time operating voltage and the collection line current.

The second calculation module 203 is configured to calculate a short circuit ratio of the monitoring point and a critical short circuit ratio of the monitoring point according to a nominal voltage of the monitoring point, the system's Thevenin equivalent potential and the bus real-time operating voltage.

The third calculation module 204 is configured to calculate a safety margin of the short circuit ratio of the monitoring point according to the short circuit ratio of the monitoring point and the critical short circuit ratio of the monitoring point.

The result output module 205 is configured to determine a strength division result of the voltage support strength of the renewable energy power system according to the safety margin of the short circuit ratio of the monitoring point and a set voltage support strength division criterion.

Preferably, the first calculation module 202 calculates a system's Thevenin equivalent potential of the monitoring point according to the bus real-time operating voltage and the collection line current, and a calculation formula of the system's Thevenin equivalent potential is shown as the formula (10):

$${\dot{E}}_{t} = \frac{{\dot{U}}_{t} {\dot{I}}_{t - 1} - {\dot{U}}_{t - 1} {\dot{I}}_{t}}{{\dot{I}}_{t - 1} - {\dot{I}}_{t}} \qquad ( 10 )$$

In the formula, \dot{U}ₜ is a bus operating voltage of the monitoring point at a moment t. \dot{U}ₜ₋₁ is a bus operating voltage of the monitoring point at a moment t−1. İₜ is a collection line current of the monitoring point at the moment t. İₜ₋₁ is a collection line current of the monitoring point at the moment t−1. Ėₜ is a system's Thevenin equivalent potential of the monitoring point at the moment t.

Preferably, the second calculation module 203 calculates a short circuit ratio of the monitoring point and a critical short circuit ratio of the monitoring point according to a nominal voltage of the monitoring point, the system's Thevenin equivalent potential and the bus real-time operating voltage, and calculation formulas of the short circuit ratio of the monitoring point and the critical short circuit ratio of the monitoring point are shown as the formula (11) and the formula (12), respectively:

$$SCR - {U}_{t} = \frac{{U}_{N} \cdot {E}_{t}}{{U}_{t} \cdot \vert {\dot{U}}_{t} - {\dot{E}}_{t} \vert} \qquad ( 11 )$$

$$CSCR - {U}_{t} = \frac{{U}_{N} {E}_{t}}{{U}_{t}^{2}} \qquad ( 12 )$$

In the formulas, SCR-Uₜ is a short circuit ratio of the monitoring point at a moment t. CSCR-Uₜ is a critical short circuit ratio of the monitoring point at the moment t. Ėₜ is a system's Thevenin equivalent potential of the monitoring point at the moment t. Eₜ is a modulus value of the system's Thevenin equivalent potential of the monitoring point at the moment t. \dot{U}ₜ is a bus operating voltage of the monitoring point at the moment t. Uₜ is a modulus value of the bus operating voltage of the monitoring point at the moment t. U_{N} is the nominal voltage of the monitoring point. When the monitoring point is a bus of a renewable energy plant, a value of U_{N} is a rated voltage of a voltage class corresponding to the renewable energy plant, and when the monitoring point is a terminal bus of a renewable energy unit in a renewable energy plant, the value of U_{N} is a rated voltage of the renewable energy unit.

Preferably, the third calculation module 204 calculates a safety margin of the short circuit ratio of the monitoring point according to the short circuit ratio of the monitoring point and the critical short circuit ratio of the monitoring point, and a calculation formula of the safety margin of the short circuit ratio of the monitoring point is shown as formula (13):

$$M {g}_{t} = \frac{SCR - {U}_{t} - CSCR - {U}_{t}}{SCR - {U}_{t}} \times 100 \qquad ( 13 )$$

In the formula, Mgₜ is the safety margin of the short circuit ratio of the monitoring point, which is expressed as a percentage and is dimensionless. SCR-Uₜ is a short circuit ratio of the monitoring point at a moment t. CSCR-Uₜ is a critical short circuit ratio of the monitoring point at the moment t.

Preferably, the result output module 205 determines a strength division result of the voltage support strength of the renewable energy power system according to the safety margin of the short circuit ratio of the monitoring point and a set voltage support strength division criterion, and the voltage support strength division criterion includes followings.

In response to Mgₜ<K₁, it is determined that the renewable energy power system is a system with weak voltage support strength, where K₁ is a safety margin of the short circuit ratio of the monitoring point determined through calculation when an operating voltage becomes lower than a voltage threshold K₄ via low voltage ride through for an operating condition where reactive power compensation of the renewable energy power system is K₃, 0<K₁, K₃, K₄<1.

In response to K₁≤Mg₁<K₂, it is determined that the renewable energy power system is a system with medium voltage support strength, where K₂ is a safety margin of the short circuit ratio of the monitoring point determined through calculation when renewable energy active power output reaches K₅ of transmission capacity of the renewable energy power system for an operating condition where reactive power compensation of the renewable energy power system is K₃, 0<K₂, K₅<1.

In response to Mgₜ≥K₂, it is determined that the renewable energy power system is a system with strong voltage support strength.

Operations of determining the voltage support strength of the renewable energy power system based on electrical parameters collected from the monitoring point in real time performed by the apparatus for determining the voltage support strength of the renewable energy power system according to the preferred embodiment are the same as the operations taken by the method for determining the voltage support strength of the renewable energy power system according to the present disclosure, and achieve the same technical effect as that of the operations taken by the method. Details are not repeated here.

An embodiment of the present disclosure further provides a device for determining voltage support strength of a renewable energy power system in real time, including a memory and a processor. The memory stores a computer program executable on the processor, and the processor executes the computer program, to perform some or all of operations for implementing the method.

An embodiment of the present disclosure further provides a computer-readable storage medium having stored thereon a computer program that, when executed by a processor, causes the processor to perform some or all of operations for implementing the method. The computer-readable storage medium may be a transitory computer-readable storage medium or a non-transitory computer-readable storage medium.

An embodiment of the present disclosure further provides a computer program including computer-readable code that, when running in a device, causes a processor in the device to perform some or all of operations for implementing the method.

An embodiment of the present disclosure further provides a computer program product including a non-transitory computer-readable storage medium storing a computer program that, when read and executed by a computer, causes the computer to perform some or all of operations for implementing the method. The computer program product can be implemented specifically by hardware, software or a combination thereof. In some embodiments, the computer program product is embodied as a computer storage medium, and in some other embodiments, the computer program product is embodied as a software product, such as a Software Development Kit (SDK), etc.

The present disclosure has been described with reference to a few embodiments. However, as is well known to those skilled in the art, as defined by the appended claims, other embodiments other than those disclosed above fall equivalently within the scope of the present disclosure.

Generally, all terms used in the claims are construed according to their ordinary meanings in the art unless otherwise expressly defined therein. All references to “one/said/the device, component, etc.” are openly interpreted as at least one example of the apparatus, component, etc. unless otherwise expressly stated. The operations of any of the methods disclosed here need not be run in the exact order disclosed unless explicitly stated.

Those skilled in the art will appreciate that the embodiment of the present disclosure may be provided as a method, a systems or a computer program product. Accordingly, the present disclosure may take the form of an entirely hardware embodiment, an entirely software embodiment or an embodiment combining software and hardware aspects. Further, the present disclosure may take the form of a computer program product implemented on one or more computer-usable storage media (including, but not limited to, disk storage, Compact Disc Read-only Memories (CD-ROMs), optical memories, etc.) containing computer-usable program code therein.

The present disclosure is described with reference to flowcharts and/or block diagrams of the method, the apparatus (systems) and the computer program product according to the embodiments of the present disclosure. It should be understood that each flow and/or block in the flowchart and/or block diagram, as well as a combinations of flows and/or blocks in the flowchart and/or block diagram, may be implemented by computer program instructions. These computer program instructions may be provided to a processor of a general purpose computer, a special purpose computer, an embedded processor, or other programmable data processing devices to generate a machine, such that instructions executed by the processor of the computer or other programmable data processing devices generate means for performing the functions specified in one or more flows of the flowchart and/or one or more blocks of the block diagram.

These computer program instructions may also be stored in a computer-readable memory capable of directing a computer or other programmable data processing devices to operate in a specific manner, such that the instructions stored in the computer-readable memory produce a manufacture including instruction means that perform the functions specified in one or more flows of the flowchart and/or one or more blocks of the block diagram.

These computer program instructions may also be installed onto a computer or other programmable data processing devices, such that a series of operational steps are executed on the computer or other programmable devices to produce computer-implemented processing, such that the instructions executed on the computer or other programmable devices provide operations for realizing the functions specified in one or more flows of the flowchart and/or one or more blocks of the block diagram.

Finally, it should be noted that the above embodiments are intended only to illustrate the technical solutions of the present disclosure and not to limit the technical solutions of the present disclosure. Although the present disclosure has been described in detail with reference to the above embodiments, it should be understood by those of ordinary skill in the art that modifications or equivalents may be made to the specific embodiments of the present disclosure, and any modifications or equivalents not departing from the spirit and scope of the present disclosure should be covered within the scope of protection of the claims of the present disclosure.

1. A method for determining voltage support strength of a renewable energy power system in real time, comprising:
collecting a bus real-time operating voltage and a collection line current of a monitoring point of the renewable energy power system, wherein the renewable energy power system comprises at least one renewable energy plant, each renewable energy plant comprises at least one renewable energy unit, and the monitoring point is a bus of a renewable energy plant or a terminal bus of a renewable energy unit;
calculating a system's Thevenin equivalent potential of the monitoring point according to the bus real-time operating voltage and the collection line current;
calculating a short circuit ratio of the monitoring point and a critical short circuit ratio of the monitoring point according to a nominal voltage of the monitoring point, the system's Thevenin equivalent potential and the bus real-time operating voltage;
calculating a safety margin of the short circuit ratio of the monitoring point according to the short circuit ratio of the monitoring point and the critical short circuit ratio of the monitoring point; and
determining a strength division result of the voltage support strength of the renewable energy power system according to the safety margin of the short circuit ratio of the monitoring point and a set voltage support strength division criterion.

2. The method of claim 1, wherein a calculation formula of the system's Thevenin equivalent potential is:
$${\dot{E}}_{t} = \frac{{\dot{U}}_{t} {\dot{I}}_{t - 1} - {\dot{U}}_{t - 1} {\dot{I}}_{t}}{{\dot{I}}_{t - 1} - {\dot{I}}_{t}}$$
wherein \dot{U}ₜ is a bus operating voltage of the monitoring point at a moment t, \dot{U}ₜ₋₁ is a bus operating voltage of the monitoring point at a moment t−1, It is a collection line current of the monitoring point at the moment t, İₜ₋₁ is a collection line current of the monitoring point at the moment t−1, and Ėₜ is a system's Thevenin equivalent potential of the monitoring point at the moment t.

3. The method of claim 1, wherein calculation formulas of the short circuit ratio of the monitoring point and the critical short circuit ratio of the monitoring point are:
$$SCR - {U}_{t} = \frac{{U}_{N} \cdot {E}_{t}}{{U}_{t} \cdot \vert {\dot{U}}_{t} - {\dot{E}}_{t} \vert} \\ CSCR - {U}_{t} = \frac{{U}_{N} {E}_{t}}{{U}_{t}^{2}}$$
wherein SCR-Uₜ is a short circuit ratio of the monitoring point at a moment t, CSCR-Uₜ is a critical short circuit ratio of the monitoring point at the moment t, Ėₜ is a system's Thevenin equivalent potential of the monitoring point at the moment t, Eₜ is a modulus value of the system's Thevenin equivalent potential of the monitoring point at the moment t, \dot{U}ₜ is a bus operating voltage of the monitoring point at the moment t, Uₜ is a modulus value of the bus operating voltage of the monitoring point at the moment t, and U_{N} is the nominal voltage of the monitoring point, wherein when the monitoring point is a bus of a renewable energy plant, a value of U_{N} is a rated voltage of a voltage class corresponding to the renewable energy plant, and when the monitoring point is a terminal bus of a renewable energy unit in a renewable energy plant, the value of U_{N} is a rated voltage of the renewable energy unit.

4. The method of claim 1, wherein a calculation formula of the safety margin of the short circuit ratio of the monitoring point is:
$$M {g}_{t} = \frac{SCR - {U}_{t} - CSCR - {U}_{t}}{SCR - {U}_{t}} \times 100$$
wherein Mgₜ is the safety margin of the short circuit ratio of the monitoring point, which is expressed as a percentage and is dimensionless; SCR-Uₜ is a short circuit ratio of the monitoring point at a moment t, and CSCR-Uₜ is a critical short circuit ratio of the monitoring point at the moment t.

5. The method of claim 1, wherein the voltage support strength division criterion comprises:
in response to Mgₜ<K₁, determining that the renewable energy power system is a system with weak voltage support strength, wherein K₁ is a safety margin of the short circuit ratio of the monitoring point determined through calculation when an operating voltage becomes lower than a voltage threshold K₄ via low voltage ride through for an operating condition where reactive power compensation of the renewable energy power system is K₃, 0<K₁, K₃, K₄<1;
in response to K₁≤Mgₜ<K₂, determining that the renewable energy power system is a system with medium voltage support strength, wherein K₂ is a safety margin of the short circuit ratio of the monitoring point determined through calculation when renewable energy active power output reaches K₅ of transmission capacity of the renewable energy power system for an operating condition where reactive power compensation of the renewable energy power system is K₃, 0<K₂, K₅<1; and
in response to Mgₜ≥K₂, determining that the renewable energy power system is a system with strong voltage support strength;
wherein Mgₜ is the safety margin of the short circuit ratio of the monitoring point.

6. An apparatus for determining voltage support strength of a renewable energy power system in real time, comprising:
a memory for storing computer executable instructions; and
a processor connected to the memory, wherein the processor is configured to execute the computer executable instructions to:
collect a bus real-time operating voltage and a collection line current of a monitoring point of the renewable energy power system, wherein the renewable energy power system comprises at least one renewable energy plant, each renewable energy plant comprises at least one renewable energy unit, and the monitoring point is a bus of a renewable energy plant or a terminal bus of a renewable energy unit;
calculate a system's Thevenin equivalent potential of the monitoring point according to the bus real-time operating voltage and the collection line current;
calculate a short circuit ratio of the monitoring point and a critical short circuit ratio of the monitoring point according to a nominal voltage of the monitoring point, the system's Thevenin equivalent potential and the bus real-time operating voltage;
calculate a safety margin of the short circuit ratio of the monitoring point according to the short circuit ratio of the monitoring point and the critical short circuit ratio of the monitoring point; and
determine a strength division result of the voltage support strength of the renewable energy power system according to the safety margin of the short circuit ratio of the monitoring point and a set voltage support strength division criterion.

7. The apparatus of claim 6, wherein a calculation formula of the system's Thevenin equivalent potential is:
$${\dot{E}}_{t} = \frac{{\dot{U}}_{t} {\dot{I}}_{t - 1} - {\dot{U}}_{t - 1} {\dot{I}}_{t}}{{\dot{I}}_{t - 1} - {\dot{I}}_{t}}$$
wherein \dot{U}ₜ is a bus operating voltage of the monitoring point at a moment t, \dot{U}ₜ₋₁ is a bus operating voltage of the monitoring point at a moment t−1, İₜ is a collection line current of the monitoring point at the moment t, İₜ₋₁ is a collection line current of the monitoring point at the moment t−1, and Ėₜ is a system's Thevenin equivalent potential of the monitoring point at the moment t.

8. The apparatus of claim 6, wherein calculation formulas of the short circuit ratio of the monitoring point and the critical short circuit ratio of the monitoring point are:
$$SCR - {U}_{t} = \frac{{U}_{N} \cdot {E}_{t}}{{U}_{t} \cdot \vert {\dot{U}}_{t} - {\dot{E}}_{t} \vert} \\ CSCR - {U}_{t} = \frac{{U}_{N} {E}_{t}}{{U}_{t}^{2}}$$
wherein SCR-Uₜ is a short circuit ratio of the monitoring point at a moment t, CSCR-Uₜ is a critical short circuit ratio of the monitoring point at the moment t, Ėₜ is a system's Thevenin equivalent potential of the monitoring point at the moment t, Eₜ is a modulus value of the system's Thevenin equivalent potential of the monitoring point at the moment t, \dot{U}ₜ is a bus operating voltage of the monitoring point at the moment t, Uₜ is a modulus value of the bus operating voltage of the monitoring point at the moment t, and U_{N} is the nominal voltage of the monitoring point, wherein when the monitoring point is a bus of a renewable energy plant, a value of U_{N} is a rated voltage of a voltage class corresponding to the renewable energy plant, and when the monitoring point is a terminal bus of a renewable energy unit in a renewable energy plant, the value of U_{N} is a rated voltage of the renewable energy unit.

9. The apparatus of claim 6, wherein a calculation formula of the safety margin of the short circuit ratio of the monitoring point is:
$$M {g}_{t} = \frac{SCR - {U}_{t} - CSCR - {U}_{t}}{SCR - {U}_{t}} \times 100$$
wherein Mgₜ is the safety margin of the short circuit ratio of the monitoring point, which is expressed as a percentage and is dimensionless; SCR-Uₜ is a short circuit ratio of the monitoring point at a moment t, and CSCR-Uₜ is a critical short circuit ratio of the monitoring point at the moment t.

10. The apparatus of claim 6, wherein the voltage support strength division criterion comprises:
in response to Mgₜ<K₁, determining that the renewable energy power system is a system with weak voltage support strength, wherein K₁ is a safety margin of the short circuit ratio of the monitoring point determined through calculation when an operating voltage becomes lower than a voltage threshold K₄ via low voltage ride through for an operating condition where reactive power compensation of the renewable energy power system is K₃, 0<K₁, K₃, K₄<1;
in response to K₁≤Mgₜ<K₂, determining that the renewable energy power system is a system with medium voltage support strength, wherein K₂ is a safety margin of the short circuit ratio of the monitoring point determined through calculation when renewable energy active power output reaches K₅ of transmission capacity of the renewable energy power system for an operating condition where reactive power compensation of the renewable energy power system is K₃, 0<K₂, K₅<1; and
in response to Mgₜ≥K₂, determining that the renewable energy power system is a system with strong voltage support strength;
wherein Mgₜ is the safety margin of the short circuit ratio of the monitoring point.

11. (canceled)

12. A non-transitory computer-readable storage medium, having stored thereon a computer program that, when executed by at least one processor, performs a method for determining voltage support strength of a renewable energy power system in real time, the method comprising:
collecting a bus real-time operating voltage and a collection line current of a monitoring point of the renewable energy power system, wherein the renewable energy power system comprises at least one renewable energy plant, each renewable energy plant comprises at least one renewable energy unit, and the monitoring point is a bus of a renewable energy plant or a terminal bus of a renewable energy unit;
calculating a system's Thevenin equivalent potential of the monitoring point according to the bus real-time operating voltage and the collection line current;
calculating a short circuit ratio of the monitoring point and a critical short circuit ratio of the monitoring point according to a nominal voltage of the monitoring point, the system's Thevenin equivalent potential and the bus real-time operating voltage;
calculating a safety margin of the short circuit ratio of the monitoring point according to the short circuit ratio of the monitoring point and the critical short circuit ratio of the monitoring point; and
determining a strength division result of the voltage support strength of the renewable energy power system according to the safety margin of the short circuit ratio of the monitoring point and a set voltage support strength division criterion.

13. (canceled)

14. The non-transitory computer-readable storage medium of claim 12, wherein a calculation formula of the system's Thevenin equivalent potential is:
$${\dot{E}}_{t} = \frac{{\dot{U}}_{t} {\dot{I}}_{t - 1} - {\dot{U}}_{t - 1} {\dot{I}}_{t}}{{\dot{I}}_{t - 1} - {\dot{I}}_{t}}$$
wherein \dot{U}ₜ is a bus operating voltage of the monitoring point at a moment t, \dot{U}ₜ₋₁ is a bus operating voltage of the monitoring point at a moment t−1, It is a collection line current of the monitoring point at the moment t, İₜ₋₁ is a collection line current of the monitoring point at the moment t−1, and Ėₜ is a system's Thevenin equivalent potential of the monitoring point at the moment t.

15. The non-transitory computer-readable storage medium of claim 12, wherein calculation formulas of the short circuit ratio of the monitoring point and the critical short circuit ratio of the monitoring point are:
$$SCR - {U}_{t} = \frac{{U}_{N} \cdot {E}_{t}}{{U}_{t} \cdot \vert {\dot{U}}_{t} - {\dot{E}}_{t} \vert} \\ CSCR - {U}_{t} = \frac{{U}_{N} {E}_{t}}{{U}_{t}^{2}}$$
wherein SCR-Uₜ is a short circuit ratio of the monitoring point at a moment t, CSCR-Uₜ is a critical short circuit ratio of the monitoring point at the moment t, Ėₜ is a system's Thevenin equivalent potential of the monitoring point at the moment t, Eₜ is a modulus value of the system's Thevenin equivalent potential of the monitoring point at the moment t, \dot{U}ₜ is a bus operating voltage of the monitoring point at the moment t, Uₜ is a modulus value of the bus operating voltage of the monitoring point at the moment t, and U_{N} is the nominal voltage of the monitoring point, wherein when the monitoring point is a bus of a renewable energy plant, a value of U_{N} is a rated voltage of a voltage class corresponding to the renewable energy plant, and when the monitoring point is a terminal bus of a renewable energy unit in a renewable energy plant, the value of U_{N} is a rated voltage of the renewable energy unit.

16. The non-transitory computer-readable storage medium of claim 12, wherein a calculation formula of the safety margin of the short circuit ratio of the monitoring point is:
$$M {g}_{t} = \frac{SCR - {U}_{t} - CSCR - {U}_{t}}{SCR - {U}_{t}} \times 100$$
wherein Mgₜ is the safety margin of the short circuit ratio of the monitoring point, which is expressed as a percentage and is dimensionless; SCR-Uₜ is a short circuit ratio of the monitoring point at a moment t, and CSCR-Uₜ is a critical short circuit ratio of the monitoring point at the moment t.

17. The non-transitory computer-readable storage medium of claim 12, wherein the voltage support strength division criterion comprises:
in response to Mgₜ<K₁, determining that the renewable energy power system is a system with weak voltage support strength, wherein K₁ is a safety margin of the short circuit ratio of the monitoring point determined through calculation when an operating voltage becomes lower than a voltage threshold K₄ via low voltage ride through for an operating condition where reactive power compensation of the renewable energy power system is K₃, 0<K₁, K₃, K₄<1;
in response to K₁≤Mgₜ<K₂, determining that the renewable energy power system is a system with medium voltage support strength, wherein K₂ is a safety margin of the short circuit ratio of the monitoring point determined through calculation when renewable energy active power output reaches K₅ of transmission capacity of the renewable energy power system for an operating condition where reactive power compensation of the renewable energy power system is K₃, 0<K₂, K₅<1; and
in response to Mgₜ≥K₂, determining that the renewable energy power system is a system with strong voltage support strength;
wherein Mgₜ is the safety margin of the short circuit ratio of the monitoring point.
